(19) United States
(12) Patent Application Publication
(10) Pub. No.: US 2025/0038130 A1
(43) Pub. Date: Jan. 30, 2025

(54) WAFER AND CHIP THEREOF

(71) Applicant: CHIPBOND TECHNOLOGY CORPORATION, Hsinchu (TW)

(72) Inventors: Sheng-Han Yang, Kaohsiung City (TW); Shih-Chieh Chang, Chiayi County (TW)

(21) Appl. No.: 18/771,070

(22) Filed: Jul. 12, 2024

(30) Foreign Application Priority Data
Jul. 25, 2023 (TW) 112127821

(51) Int. Cl. H01L 23/00; H01L 23/58

(52) U.S. Cl. CPC H01L 23/562; H01L 23/585

(57) ABSTRACT

A wafer includes chips, a scribe lane, a metal layer and an inhibitor made of a nonconductive material. The metal layer is provided on the scribe lane and the chip located next to the scribe lane. The inhibitor covers the scribe lane and the chip next to the scribe line and includes a first removed part and an inhibition part which are located above a second removed part and a residual part of the metal layer, respectively. The scribe lane, the first and second removed parts are removed, and the inhibition part and the residual part are retained on each of the chips after a wafer cutting process. The inhibitor is provided to prevent the residual part of the metal layer from being lifted up or generating a metal burr during the wafer cutting process.

### CROSS-REFERENCE TO RELATED APPLICATIONS

This application claims priority to R.O.C Patent Application No. 112127821 filed Jul. 25, 2023, the disclosure of which is hereby incorporated by reference in its entirety.

### FIELD OF THE INVENTION

This invention relates to a wafer and a chip thereof, and more particularly to a wafer and a chip able to prevent a metal layer from being lifted up or generating a metal burr during a wafer cutting process.

### BACKGROUND OF THE INVENTION

With reference to FIGS. 1 to 3, a conventional wafer 10 includes chips 11, scribe lanes 12 and at least one metal layer 13. Each of the scribe lanes 12 is located between the adjacent chips 11, and the metal layer 13 which may be test pad(s), mark(s) or circuit line(s) is located on the scribe lanes 12 and extended to the chips 11 located next to the scribe lanes 12.

The wafer 10 is cut along the scribe lanes 12 to separate the chips 11 in a cutting process, but a part 13a of the metal layer 13 may be remained on the chips 11. The metal layer 13 has ductility so the residual part 13a may be lifted up or generate a metal burr 13b.

Referring to FIG. 3, while a lead 21 on a circuit board is bonded to a bump 14 of the chip 11, the lead 21 may contact the residual part 13a which is lifted up or contact the metal burr 13b to bring short circuit or electrical error problem to the chips 11 and the circuit board.

### SUMMARY OF THE INVENTION

One object of the present invention is to provide a wafer and a chip of the wafer which includes an inhibitor covering a scribe lane and a chip located next to the scribe lane. The inhibitor is provided to improve tensile strength of a metal layer located on the scribe lane and the chip so as to prevent a residual part of the metal layer generated after cutting from being lifted up or generating a metal burr.

A wafer of the present invention includes chips, a scribe lane located between the adjacent chips, a metal layer and an inhibitor. The metal layer is provided on the scribe lane and extended to be on the chip which is located next to the scribe lane, and the metal layer includes a second removed part and a residual part. The inhibitor which is made of a nonconductive material covers the scribe lane and the chip next to the scribe lane and includes a first removed part located above the second removed part of the metal layer and an inhibition part located above the residual part of the metal layer. After a cutting process of the wafer, the scribe lane, the first and second removed parts located on the scribe lane are removed, and the inhibition part and the residual part are still located on the chip.

A chip of the present invention includes a residual part and an inhibition part which is located above the residual part and made of a nonconductive material. The inhibition part includes a first cut surface and a first side wall which are opposite to each other, the first cut surface is visible from a side wall of the chip. The inhibition part is retained on an active surface of the chip after removing a first removed part of an inhibitor. The residual part includes a second cut surface and a second side wall which are opposite to each other, the second cut surface is visible from the side wall of the chip. The residual part is retained on the chip after removing a second removed part of a metal layer.

The inhibitor covering the scribe lane and the chip located next to the scribe lane is provided to increase tensile strength of the metal layer. Because of the inhibitor, the residual part of the metal layer, which is retained on the chip, will not be lifted up or generate a metal burr during removing the scribe lane, the first and second removed parts located on the scribe lane. In addition, the inhibition part retained on the chip can support a lead of a circuit board (not shown) bonded to the chip to prevent the lead from contacting the first cut surface of the inhibition part and/or the second cut surface of the residual part to cause short circuit or electrical abnormality.

### BRIEF DESCRIPTION OF DRAWINGS

FIG. 1 is a top view diagram illustrating a conventional wafer.

FIG. 2 is a cross-section view diagram illustrating a conventional wafer.

FIG. 3 is a cross-section view diagram illustrating a conventional chip.

FIG. 4 is a top view diagram illustrating a part of a wafer in accordance with one embodiment of the present invention.

FIG. 5 is a cross-section view diagram illustrating a part of a wafer in accordance with one embodiment of the present invention.

FIG. 6 is a cross-section view diagram illustrating a part of a wafer in accordance with one embodiment of the present invention.

FIG. 7 is a cross-section view diagram illustrating a chip in accordance with one embodiment of the present invention.

FIG. 8 is a cross-section view diagram illustrating a chip in accordance with one embodiment of the present invention.

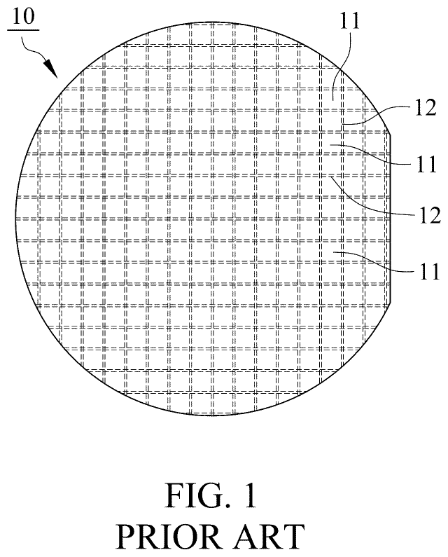

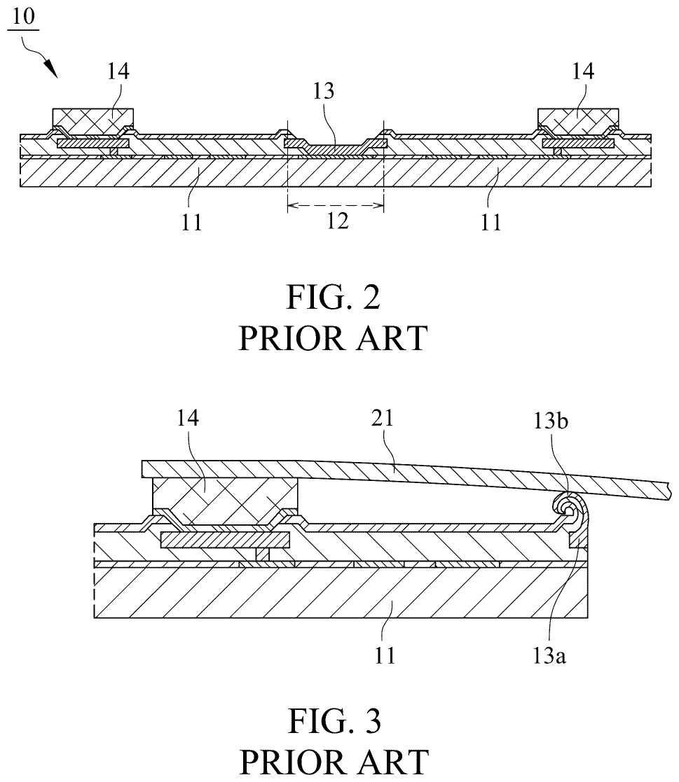

### DETAILED DESCRIPTION OF THE INVENTION

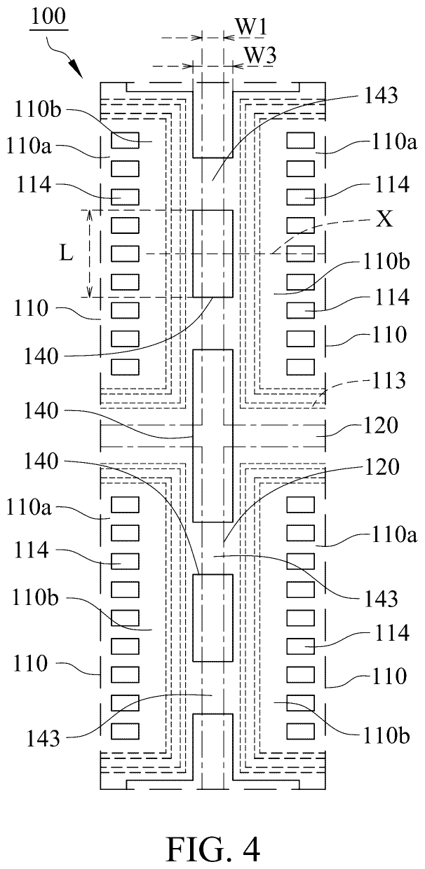

With reference to FIGS. 4 to 6, a wafer 100 in accordance with one embodiment of the present invention includes chips 110, at least one scribe lane 120 located between the adjacent chips 110, a metal layer 130 and at least one inhibitor 140 which is made of a nonconductive material, e.g. polymeric material or other nonconductive material. Each of the chips 110 includes a protective layer 111, at least one conductive pad 112, a seal ring 113 surrounding the conductive pad 112 and at least one bump 114. An active surface 110a of each of the chips 110 is the surface of the protective layer 111, the protective layer 111 covers the seal ring 113 but not cover the conductive pad 112 which is located on a bump arrangement area 110b defined on the active surface 110a, and the bump 140 is electrically connected to the conductive pad 112.

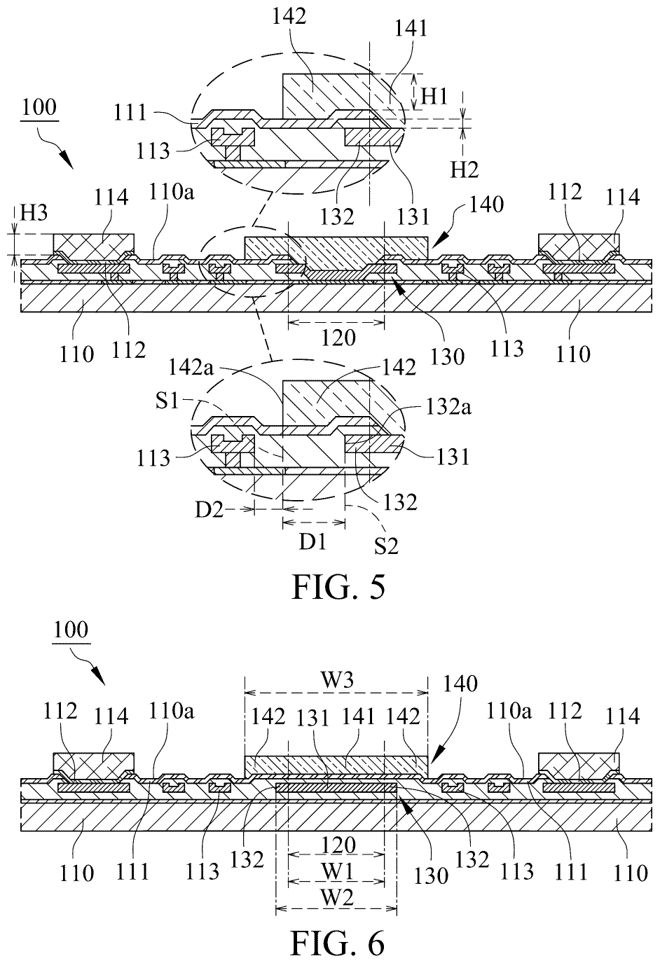

With reference to FIGS. 5 and 6, the metal layer 130 is provided on the scribe lane 120 and extended to be on the chip 110 located next to the scribe lane 120. The metal layer 130 may be a test pad or mark as shown in FIG. 5, and it may be a circuit line as shown in FIG. 6. The metal layer 130 includes a second removed part 131 located on the scribe lane 120 and a residual part 132 located on the chip 110 and covered by the protective layer 111. Referring to FIG. 5, the second removed part 131 of the metal layer 130 which is the test pad or mark is not covered by the protective layer 111, and referring to FIG. 6, the second removed part 131 of the metal layer 130 which is the circuit line is covered by the protective layer 111.

With reference to FIGS. 4 to 6, the inhibitor 140 covers the scribe lane 120 and the chip 110 located next to the scribe lane 120. Preferably, the wafer 100 includes a plurality of inhibitors 140 as shown in FIG. 4, and there is an opening 143 which is located between the adjacent inhibitors 140 and communicates with the bump arrangement area 110b defined on the active surface 110a of the chip 110. An underfill (not shown) can flow to the bump arrangement area 110b via the opening 143 to seal the bump 114 and a lead (not shown) bonded to the bump 114. Along the direction of an axis line X extending from the bump arrangement area 110b toward the inhibitor 140, a first width W1 of the scribe lane 120 is less than a second width W2 of the metal layer 130, and the second width W2 of the metal layer 130 is less than a third width W3 of the inhibitor 140. Along the direction perpendicular to the axis line X, the inhibitor 140 is designed to have a length L greater than or equal to 60 μm in order to improve the adhesive strength of the inhibitor 140 to the wafer 100.

With reference to FIGS. 5 and 6, the inhibitor 140 includes a first removed part 141 and an inhibition part 142, the first removed part 141 is located above the second removed part 131 of the metal layer 130 and the inhibition part 142 is located above the residual part 132 of the metal layer 130. While the metal layer 130 is the test pad or mark as shown in FIG. 5, the first removed part 141 of the inhibitor 140 covers the second removed part 131 of the metal layer 130. If the metal layer 130 is the circuit line as shown in FIG. 6, the first removed part 141 of the inhibitor 140 covers the protective layer 111, and the protective layer 111 covers the second removed part 131 of the metal layer 130. The protective layer 111 is covered by the inhibitor 140 and located between the inhibition part 142 of the inhibitor 140 and the residual part 132 of the metal layer 130.

With reference to FIGS. 5 and 6, a first height H1 of the inhibition part 142 of the inhibitor 140 is higher than a second height H2 of the protective layer 111 such that the inhibition part 142 can increase flexural strength of the protective layer 111. A third height H3 of the bump 114 protruding from the protective layer 111 is not less than the first height H1 of the inhibition part 142, and preferably, the third height H3 is higher than the first height H1, and the difference between the third height H3 and the first height H1 is less than or equal to 7 μm.

With reference to FIGS. 5 and 6, the inhibition part 142 of the inhibitor 140 has a first side wall 142a close to the seal ring 113, and the residual part 132 of the metal layer 130 has a second side wall 132a close to the seal ring 113. A first distance D1 between a first imaginary line S1 extending from the first side wall 142a and a second imaginary line S2 extending from the second side wall 132a is greater than or equal to 5 μm, and a second distance D2 between the seal ring 113 and the first imaginary line S1 is greater than or equal to 1 μm.

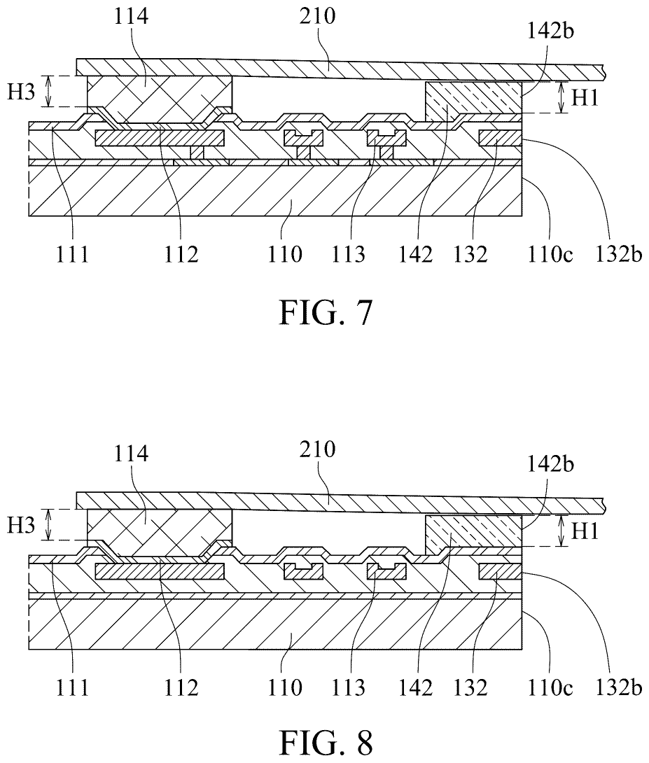

With reference to FIGS. 5 to 8, a cutting tool (not shown) is used to cut the wafer 100 into the chips 110 along the scribe lane 120 during a cutting process, as a result, each of the chips 110 has a side wall 110c. Referring to FIGS. 7 and 8, during the wafer cutting process, the scribe lane 120, the first removed part 141 and the second removed part 131 located on the scribe lane 120 are removed by the cutting tool, and the inhibition part 142 and the residual part 132 are retained on the chip 110. The inhibition part 142 covers the protective layer 111 and has a first cut surface 142b which is opposite to the first side wall 142a and exposed on the side wall 110c of the chip 110. The residual part 132 has a second cut surface 132b which is opposite to the second side wall 132a and exposed on the side wall 110c of the chip 110. The first cut surface 142b of the inhibition part 142 and the second cut surface 132b of the residual part 132 are flush with the side wall 110c of the chip 110. Preferably, each of the chips 110 includes multiple inhibition parts 142, and the opening 143 is located between the adjacent inhibition parts 142.

With reference to FIGS. 7 and 8, during the wafer cutting process, the first removed part 141 is removed and the inhibition part 142 is retained on the active surface 110a of the chip 110, thus, the inhibition part 142 has a length as same as the length L of the inhibitor 140. The inhibitor 140 is provided to cover the scribe lane 120 and the chip 110 located next to the scribe lane 120 to improve tensile strength of the metal layer 130 and further prevent the residual part 132 located on the chip 110 from being lifted up or generating a metal burr. Because the inhibition part 142 is retained on the chip 110 and its first height H1 is not higher than the third height H3 of the bump 114, the inhibition part 142 can support a lead 210 of a circuit board (not shown) bonded to the bump 114 and prevent the lead 210 from contacting the first cut surface 142b of the inhibition part 142 and/or the second cut surface 132b of the residual part 132 to cause short circuit or electrical abnormality.

While this invention has been particularly illustrated and described in detail with respect to the preferred embodiments thereof, it will be clearly understood by those skilled in the art that is not limited to the specific features shown and described and various modified and changed in form and details may be made without departing from the scope of the claims.

1. A wafer comprising:
a plurality of chips;
at least one scribe lane located between the adjacent chips;
a metal layer disposed on the at least one scribe lane and the chip located next to the at least one scribe lane; and
an inhibitor made of a nonconductive material and covering the at least one scribe lane and the chip located next to the at least one scribe lane, the inhibitor includes a first removed part and an inhibition part, the metal layer includes a second removed part and a residual part, the first removed part is located above the second removed part and the inhibition part is located above the residual part, wherein the at least one scribe lane, the first removed part and the second removed part located on the at least one scribe lane are configured to be removed and the inhibition part and the residual part are configured to be retained on each of the plurality of chips after a cutting process.

2. The wafer in accordance with claim 1, wherein each of the plurality of chips includes a protective layer, the residual part of the metal layer is covered by the protective layer, the second removed part of the metal layer is covered by the first removed part of the inhibitor and is not covered by the protective layer, the protective layer is covered by the inhibitor and located between the inhibition part of the inhibitor and the residual part of the metal layer, and a first height of the inhibition part is higher than a second height of the protective layer.

3. The wafer in accordance with claim 1, wherein each of the plurality of chips includes a seal ring and at least one conductive pad surrounded by the seal ring, the inhibition part of the inhibitor includes a first side wall close to the seal ring and the residual part of the metal layer includes a second side wall close to the seal ring, a first distance between a first imaginary line extending from the first side wall and a second imaginary line extending from the second side wall is greater than or equal to 5 μm.

4. The wafer in accordance with claim 3, wherein a second distance between the seal ring and the first imaginary line is greater than or equal to 1 μm.

5. The wafer in accordance with claim 2, wherein each of the plurality of chips further includes at least one bump, a third height of the at least one bump protruding from the protective layer is higher than or equal to the first height of the inhibition part.

6. The wafer in accordance with claim 5, wherein the third height is higher than the first height, and a difference between the third height and the first height is less than or equal to 7 μm.

7. The wafer in accordance with claim 1 comprising a plurality of inhibitors, wherein an opening located between the adjacent inhibitors communicates with a bump arrangement area defined on an active surface of each of the plurality of chips.

8. The wafer in accordance with claim 1, wherein a bump arrangement area is defined on an active surface of each of the plurality of chips, along a direction of an axis line extending from the bump arrangement area toward the inhibitor, a first width of the at least one scribe lane is less than a second width of the metal layer, and the second width of the metal layer is less than a third width of the inhibitor.

9. The wafer in accordance with claim 8, wherein a length of the inhibitor is greater than or equal to 60 μm along a direction perpendicular to the axis line.

10. A chip comprising:
an inhibition part made of a nonconductive material and including a first cut surface and a first side wall opposite to each other, the first cut surface is exposed on a side wall of the chip; and
a residual part including a second cut surface and a second side wall opposite to each other, the second cut surface is exposed on the side wall of the chip, wherein the inhibition part is retained on an active surface of the chip after removing a first removed part of an inhibitor, the residual part is retained on the chip after removing a second removed part of a metal layer, and the inhibition part is located above the residual part.

11. The chip in accordance with claim 10 further comprising a protective layer, wherein the residual part is covered by the protective layer, the protective layer is covered by the inhibition part and located between the inhibition part and the residual part, a first height of the inhibition part is higher than a second height of the protective layer.

12. The chip in accordance with claim 10, wherein a first distance between a first imaginary line extending from the first side wall of the inhibition part and a second imaginary line extending from the second side wall of the residual part is greater than or equal to 5 μm.

13. The chip in accordance with claim 10, wherein the first cut surface of the inhibition part and the second cut surface of the residual part are flush with the side wall of the chip.

14. The chip in accordance with claim 12 further comprising a seal ring and at least one conductive pad surrounded by the seal ring, wherein a second distance between the seal ring and the first imaginary line extending from the first side wall of the inhibition part is greater than or equal to 1 μm.

15. The chip in accordance with claim 11 further comprising at least one bump, wherein a third height of the at least one bump protruding from the protective layer is higher than or equal to first height of the inhibition part.

16. The chip in accordance with claim 15, wherein the third height is higher than the first height, and a difference between the third height and the first height is less than or equal to 7 μm.

17. The chip in accordance with claim 10 comprising a plurality of inhibition parts, wherein an opening located between the adjacent inhibitors communicates with a bump arrangement area defined on the active surface of the chip.

18. The chip in accordance with claim 10, wherein a length of the inhibition part is greater than or equal to 60 μm.
